(19) United States
(12) Patent Application Publication
(10) Pub. No.: US 2003/0215960 A1
(43) Pub. Date: Nov. 20, 2003

(54) Method of fabricating ferroelectric capacitor

(76) Inventor: Toshiro Mitsuhashi, Tokyo (JP)

Correspondence Address: VOLENTINE FRANCOS, PLLC, Suite 150, 12200 Sunrise Vally Drive, Reston, VA, 20191, US

(21) Appl. No.: 10/305,243

(22) Filed: Nov. 27, 2002

(30) Foreign Application Priority Data
May 20, 2002 (JP) 145011/2002

(51) Int. Cl. H01L 21/8242; H01L 21/00

(52) U.S. Cl. 438/3; 438/240

(57) ABSTRACT

In a method of fabricating a ferroelectric capacitor, a semiconductor substrate is provided. Then, an oxide film is formed on the semiconductor substrate. Next, an adhesion layer, a lower electrode film, a ferroelectric film, an upper electrode film, and an etching mask are formed on the oxide film in that order. A resist pattern is formed on the etching mask. The etching mask is etched using the resist pattern as a mask. Further, the upper electrode film is etched using the etching mask as a mask to form an upper electrode. Next, a protective film is formed on the entire upper surface of a structure obtained above. Then, the protective film is etched back so as to remain a portion thereof on the sidewall of the upper electrode. The ferroelectric film and the lower electrode film is etched to form a lower electrode. Finally, the etching mask and the adhesion layer are removed.

### BACKGROUND OF THE INVENTION

The present invention relates to a method of fabricating a capacitor (hereinafter referred to as a ferroelectric capacitor) of a semiconductor memory (Ferroelectric RAM/FeRAM).

A ferroelectric capacitor has a construction wherein an area of an upper electrode is smaller than that of a ferroelectric film and a lower electrode, underlying the former, respectively, in order to eliminate the effect of damage incurred when working on the ferroelectric film and the lower electrode, respectively. With such a construction as described, however, it is considered difficult to cope with the need for more miniaturization in future, so that fabrication of a capacitor of a stack structure is under study.

A method of fabricating a capacitor of such a stack structure is disclosed, for example, in Japanese Publication Laid-open Nos. 2000-196032 and 2001-284546.

In these publications, a stack structure including an upper electrode is fully covered by an insulation layer in order to prevent a conduction layer from being redeposited on the sidewall of a lower electrode when etching a lower electrode film of the capacitor of the stack structure.

The above-described structure is called a hard mask structure, and the lower electrode film is etched using the hard mask as a mask.

In this case, however, there has arisen a problem in that a lower electrode can not be formed with precision by etching if the stack structure including the upper electrode is covered up by the insulation layer (hard mask).

### SUMMARY OF THE INVENTION

The invention may provide a method of forming a lower electrode with precision by etching without causing a conduction layer to be redeposited on the sidewall of an upper electrode when etching a lower electrode film.

In a method of fabricating a ferroelectric capacitor of the present invention, a semiconductor substrate is provided. Then, an oxide film is formed on the semiconductor substrate. Next, an adhesion layer, a lower electrode film, a ferroelectric film, an upper electrode film, and an etching mask are formed on the oxide film in that order. A resist pattern is formed on the etching mask. The etching mask is etched using the resist pattern as a mask. Further, the upper electrode film is etched using the etching mask as a mask to form an upper electrode. Next, a protective film is formed on the entire upper surface of a structure obtained above. Then, the protective film is etched back so as to remain a portion thereof on the sidewall of the upper electrode. The ferroelectric film and the lower electrode film are etched to form a lower electrode. Finally, the etching mask and the adhesion layer are removed.

### BRIEF DESCRIPTION OF THE DRAWINGS

FIGS. 1(a) to 1(g) are sectional views illustrating a first embodiment of the invention; and

FIGS. 2(a) to 2(g) are sectional views illustrating a second embodiment of the invention.

### DETAILED DESCRIPTION OF THE PREFERRED EMBODIMENTS

Preferred embodiments of a method of fabricating a ferroelectric capacitor according to the invention are described in detail hereinafter with reference to the accompanying drawings. In the specification and drawings, constituents having in effect the same function and configuration are denoted by like reference numerals, thereby omitting duplication in description.

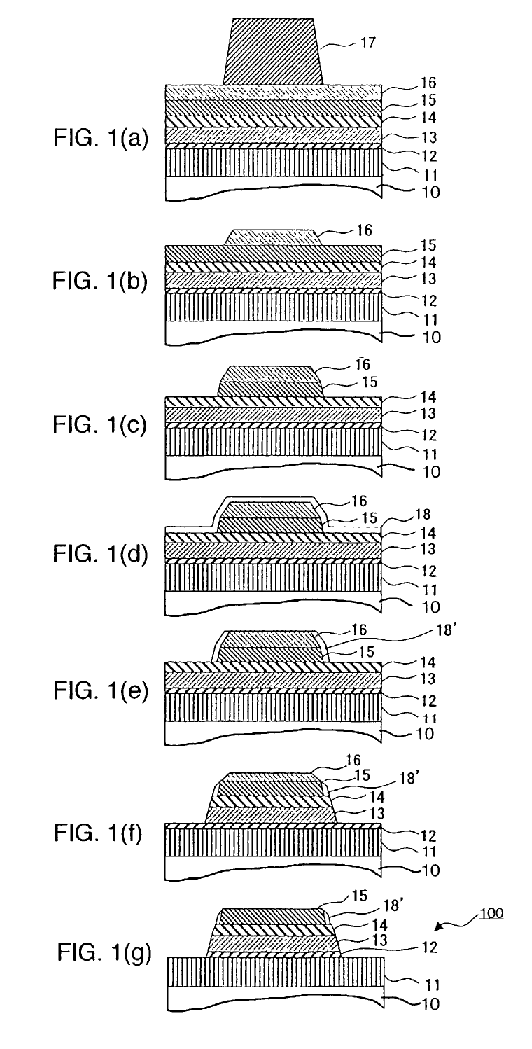

FIGS. 1(a) to 1(g) are schematic illustrations showing a first embodiment of a method of fabricating the capacitor according to the invention. Description is given in sequence hereinafter.

First, a semiconductor substrate 10 is provided. An oxide film 11 is formed on the semiconductor substrate 10 by the CVD (chemical vapor deposition) method.

As shown in FIG. 1(a), there are first deposited an adhesion layer 12 made of TiN (Titanium Nitride) formed to a thickness of 600 Å, a lower electrode film 13 made of Ir (Iridium) formed to a thickness of 1500 Å, a ferroelectric film 14 made of ferroelectric material SBT (strontium bismuth tantalite: SrBi₂Ta₂O₉) formed to a thickness of 1200 Å, an upper electrode film 15 made of Ir formed to a thickness of 1500 Å, and an etching mask 16 made of TiN formed to a thickness of 1500 Å in that order on the oxide film. Further, a resist pattern 17 is formed on top of the etching mask 16 by the photolithographic process.

Subsequently, as shown in FIG. 1(b), the etching mask 16 is etched by the dry etching method using the resist pattern 17 as a mask. After etching, the resist pattern 17 is removed by the ashing method using O2 plasma. A process up to this step is essentially the same as the conventional process.

Next, as shown in FIG. 1(c), with the present embodiment, the upper electrode film 15 only is etched by the dry etching method using the etching mask 16 as a mask, forming an upper electrode 15′. At this point in time, the ferroelectric film 14 and the lower electrode film 13 are not etched.

Then, as shown in FIG. 1(d), an oxide film 18 is formed to a thickness of 500 Å on the entire upper surface of a structure by the CVD method.

Subsequently, as shown in FIG. 1(e), the oxide film 18 is etched back by the dry etching method so as to leave out only a portion thereof (oxide film 18′) on the sidewall of a capacitor precursor. That is, the oxide film 18′ is left out on the side face of the upper electrode 15′ only.

However, because some portion of the oxide film 18′ will be removed by dry etching in the succeeding step, some portion of the oxide film 18′ may be left out on not only the side face of the upper electrode 15′ but also the side face of the etching mask 16. The oxide film 18′ thus formed functions as a protective film for perverting short-circuiting between the upper electrode 15′ and a lower electrode 13′ to be formed in a succeeding step.

Subsequently, as shown in FIG. 1(f), the ferroelectric film 14 and the lower electrode film 13 are etched by the dry etching method, forming the lower electrode 13′.

Finally, as shown in FIG. 1(g), the etching mask 16 and an exposed portion of the adhesion layer 12 are removed by the dry etching method. Following the above-described steps, a ferroelectric capacitor 100 is fabricated.

As described in the foregoing, with the present embodiment, an advantageous effect is obtained in that short-circuiting between the upper electrode 15′ and the lower electrode 13′ can be prevented by protecting the side face of the upper electrode 15′ with the oxide film 18′.

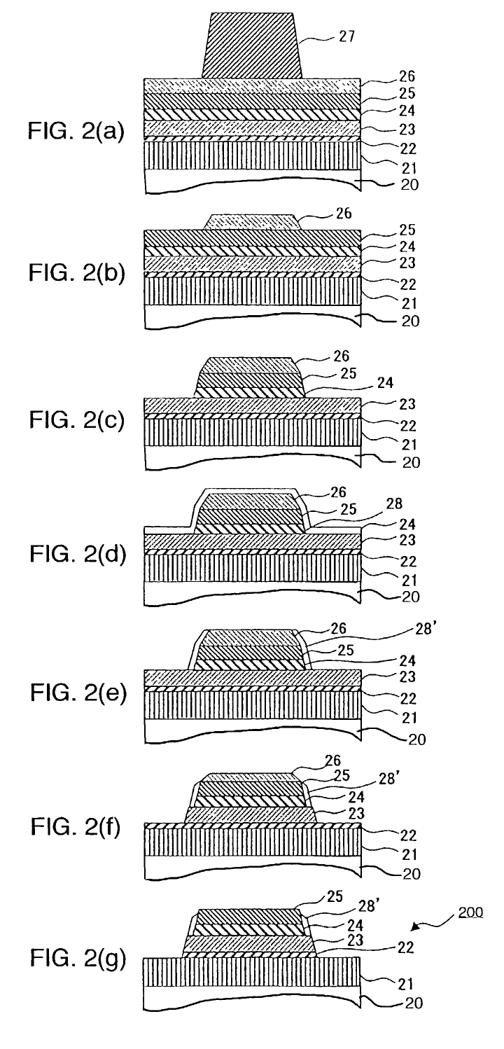

FIGS. 2(a) to 2(g) are schematic illustrations showing a second embodiment of a method of fabricating the capacitor according to the invention. Description is given in sequence hereinafter.

First, a semiconductor substrate 20 is provided. An oxide film 21 is formed on the semiconductor substrate 20 by the CVD method.

As shown in FIG. 2(a), there are first deposited an adhesion layer 22 made of TiN (Titanium Nitride) formed to a thickness of 600 Å, a lower electrode film 23 made of Ir (Iridium) formed to a thickness of 1500 Å, a ferroelectric film 24 made of ferroelectric material SBT (strontium bismuth tantalite: SrBi₂Tₐ₂O₉) formed to a thickness of 1200 Å, an upper electrode film 25 made of Ir formed to a thickness of 1500 Å, and an etching mask 26 made of TiN formed to a thickness of 1500 Åin that order on the oxide film 21. Further, a resist pattern 27 is formed on top of the etching mask 26 by the photolithographic process.

Subsequently, as shown in FIG. 2(b), the etching mask 26 is etched by the dry etching method using the resist pattern 27 as a mask. After etching, the resist pattern 27 is removed by the ashing method using O₂ plasma. A process up to this step is essentially the same as the process according to the first embodiment as shown in FIG. 1.

Next, as shown in FIG. 2(c), with the present embodiment, the upper electrode film 25 and the ferroelectric film 24 are etched by the dry etching method using the etching mask 26 as a mask, thereby forming an upper electrode 25′ and a ferroelectric 24′. At this point in time, the lower electrode film 23 is not etched.

Then, as shown in FIG. 2(d), an oxide film 28 is formed to a thickness of 500 Å on the entire upper surface of a structure by the CVD method.

Subsequently, as shown in FIG. 2(e), the oxide film 28 is etched back by the dry etching method so as to leave out only a portion thereof (oxide film 28′) on the sidewall of a capacitor precursor. That is, the oxide film 28′ is left out only on the side face of the upper electrode 25′ and the ferroelectric 24′. However, because some portion of the oxide film 28′ will be removed by dry etching in the succeeding step, some portion of the oxide film 28′ may be left out on not only the side face of the upper electrode 25′ and the ferroelectric 24′ but also the side face of the etching mask 26. The oxide film 28′ thus formed functions as a protective film for perverting short-circuiting between the upper electrode 25′ and a lower electrode 23′ to be formed in a succeeding step.

Subsequently, as shown in FIG. 2(f), the lower electrode film 23 is etched by the dry etching method. The present embodiment is characterized in that the lower electrode film 23 only is etched in the process of dry etching.

Finally, as shown in FIG. 2(g) the etching mask 26 and an exposed portion of the adhesion layer 22 are removed by the dry etching method. Following the above-described steps, a ferroelectric capacitor 200 is fabricated.

With the first embodiment, in the steps of etching as shown in FIGS. 1(e) and (f), there is a risk of the oxide film 18′ being lost when etching the ferroelectric film 14 and the lower electrode film 13 because of prolongation of etching time due to a large thickness of the films to be etched. In order to eliminate such a risk, there is the need of increasing an initial thickness of the oxide film 18 for protection, causing a problem of interference with miniaturization of a device. With the second embodiment, however, in the steps of etching as shown in FIGS. 2(e) and (f), a film to be etched is only the lower electrode 23, so that a thickness of the oxide film 28 for protection can be rendered smaller, so that an advantageous effect is obtained in that the need for the miniaturization of a device can be coped with.

A third embodiment of the invention is characterized in that, in the step of forming the protective film, shown in FIG. 2(d), according to the second embodiment, a Al₂O₃ (also referred to as aluminum oxide or alumina) film is used in place of the oxide film 28 as a protective film formed on the sidewall of a capacitor. Other steps of fabrication and materials are the same as those for the second embodiment, omitting therefore duplicated description.

With the third embodiment, an advantageous effect is obtained in that ingress of hydrogen causing deterioration in ferroelectricity can be prevented by covering the sidewall of the ferroelectric film 24 with the Al₂O₃ film.

As described hereinbefore, the preferred embodiments of the method of fabricating the ferroelectric capacitor according to the invention are described with reference to the accompanying drawings, however, the scope of the invention is not limited thereto. It is to be understood that changes and variations thereto will occur to those skilled in the art without departing the spirit or scope of the appended claims and such changes and variations are therefore intended to be embraced by said claims.

What is claimed is:

1. A method of fabricating a ferroelectric capacitor comprising:
providing a semiconductor substrate;
forming an oxide film on the semiconductor substrate;
forming an adhesion layer, a lower electrode film, a ferroelectric film, an upper electrode film, and an etching mask in that order on the oxide film;
forming a resist pattern on the etching mask;
etching the etching mask using the resist pattern as a mask; etching the upper electrode film using the etching mask as a mask to form an upper electrode;
forming a protective film on the entire upper surface of a structure obtained above;
etching back the protective film so as to remain a portion thereof on the sidewall of the upper electrode;
etching the ferroelectric film and the lower electrode film to form a lower electrode; and
removing the etching mask and the adhesion layer.

2. A method of fabricating a ferroelectric capacitor according to claim 1, wherein the oxide film is formed by a chemical vapor deposition method.

3. A method of fabricating a ferroelectric capacitor according to claim 1, wherein the etching mask is a titanium nitride layer.

4. A method of fabricating a ferroelectric capacitor according to claim 1, wherein the adhesion layer is a titanium nitride layer.

5. A method of fabricating a ferroelectric capacitor according to claim 1, wherein the ferroelectric film is made of strontium bismuth tantalite.

6. A method of fabricating a ferroelectric capacitor according to claim 1, wherein both of the upper and lower electrode films are made of iridium.

7. A method of fabricating a ferroelectric capacitor comprising:
providing a semiconductor substrate;
forming an oxide film on the semiconductor substrate;
forming an adhesion layer, a lower electrode film, a ferroelectric film, an upper electrode film, and an etching mask in that order on the oxide film;
forming a resist pattern on the etching mask;
etching the etching mask using the resist pattern as a mask;
etching the upper electrode film and the ferroelectric film using the etching mask as a mask to form an upper electrode and a ferroelectric film pattern;
forming a protective film on the entire upper surface of a structure obtained above;
etching back the protective film to remain a portion thereof on the sidewall of the upper electrode and the ferroelectric film pattern;
etching the lower electrode film to form a lower electrode; and
removing the etching mask and the adhesion layer.

8. A method of fabricating a ferroelectric capacitor according to claim 7, wherein the oxide film is formed by a chemical vapor deposition method.

9. A method of fabricating a ferroelectric capacitor according to claim 7, wherein the etching mask is a titanium nitride layer.

10. A method of fabricating a ferroelectric capacitor according to claim 7, wherein the adhesion layer is a titanium nitride layer.

11. A method of fabricating a ferroelectric capacitor according to claim 7, wherein the ferroelectric film is made of strontium bismuth tantalite.

12. A method of fabricating a ferroelectric capacitor according to claim 7, wherein both of the upper and lower electrode films are made of iridium.

13. A method of fabricating a ferroelectric capacitor comprising:
providing a semiconductor substrate;
forming an oxide film on the semiconductor substrate;
forming an adhesion layer, a lower electrode film, a ferroelectric film, an upper electrode film, and an etching mask pattern in that order on the oxide film;
etching the upper electrode film using the etching mask pattern as a mask to form an upper electrode;
forming a protective film on the sidewall of the upper electrode;
etching the ferroelectric film and the lower electrode film to form a lower electrode; and
removing the etching mask and the adhesion layer.

14. A method of fabricating a ferroelectric capacitor according to claim 13, wherein the oxide film is formed by a chemical vapor deposition method.

15. A method of fabricating a ferroelectric capacitor according to claim 13, wherein the etching mask pattern is made of titanium nitride.

16. A method of fabricating a ferroelectric capacitor according to claim 13, wherein the adhesion layer is a titanium nitride layer.

17. A method of fabricating a ferroelectric capacitor according to claim 13, wherein the ferroelectric film is made of strontium bismuth tantalite.

18. A method of fabricating a ferroelectric capacitor according to claim 13, wherein both of the upper and lower electrode films are made of iridium.
